(19) United States
(12) Patent Application Publication
(10) Pub. No.: US 2009/0269937 A1
(43) Pub. Date: Oct. 29, 2009

(54) SUBSTRATE PROCESSING APPARATUS AND METHOD OF MANUFACTURING SEMICONDUCTOR DEVICE

(75) Inventor: Yukinori ABURATANI, Toyama-shi (JP)

Correspondence Address: BRUNDIDGE & STANGER, P.C., 1700 DIAGONAL ROAD, SUITE 330, ALEXANDRIA, VA, 22314, US

(73) Assignee: Hitachi Kokusai Electric, Inc.

(21) Appl. No.: 12/365,073

(22) Filed: Feb. 3, 2009

(30) Foreign Application Priority Data
Apr. 23, 2008 (JP) 2008-112885

(51) Int. Cl. H01L 21/02; C23C 16/44

(52) U.S. Cl. 438/758; 118/715; 257/E21.002

(57) ABSTRACT

Provided are a substrate processing apparatus and a method of manufacturing a semiconductor device. The apparatus comprises a substrate processing region, a container carrying region, a housing, first and second openings, an exhaust port, a door body, and a control unit. The substrate processing region comprises a process furnace. The container carrying region comprises a carrying device. In the housing, the substrate processing region and the container carrying region are provided. The first opening is formed at the housing for carrying the container between the container carrying region and an outside region of the housing. The second opening is formed at the housing for sucking gas. The exhaust port is configured to exhaust gas from the container carrying region. The door body closes the first and second openings. The control unit controls the door body to open one of the first and second openings and close the other.

### CROSS-REFERENCE TO RELATED PATENT APPLICATION

This U.S. non-provisional patent application claims priority under 35 U.S.C. §119 of Japanese Patent Application No. 2008-112885, filed on Apr. 23, 2008, in the Japanese Patent Office, the entire contents of which are hereby incorporated by reference.

### BACKGROUND OF THE INVENTION

1. Field of the Invention

The present invention relates to a substrate processing apparatus and a method of manufacturing a semiconductor device.

For example, the present invention relates to a useful use of a semiconductor manufacturing apparatus configured to treat a semiconductor wafer (hereinafter, referred to as a wafer) by forming a thin film such as an insulating film, a metal film, and a semiconductor film on the wafer, diffusing impurities into the wafer, or performing a thermal treatment such as annealing on the wafer so as to fabricate semiconductor integrated circuit devices (hereinafter, referred to as ICs) on the wafer.

2. Description of the Prior Art

In a substrate processing apparatus such as a semiconductor manufacturing apparatus, a plurality of wafers are handled in a state that the wafers are accommodated in a container.

Examples of such a container include a front opening unified pod (FOUP) (hereinafter, simply referred to as a pod). Such a pod has an approximately cuboidal box shape with an opened side, and a door is detachably attached to the opened side of the pod.

Since wafers are carried in a state where the wafers are air-tightly placed in the pod, the wafers can be kept clean although there are particles in the atmosphere around the pod. Therefore, the cleaning level of a clean room can be lowered in the case where a semiconductor manufacturing apparatus using a pod is installed in the cleaning room. Therefore, costs required to maintain the cleaning level of the clean room can be reduced. For this reason, many recent semiconductor manufacturing apparatuses use pods as containers.

A conventional semiconductor manufacturing apparatus includes a wafer processing region in which a process furnace is provided for processing wafers, a pod carrying region in which a carrying device is provided for carrying a pod, a housing in which the wafer processing region and the pod carrying region are defined, an I/O shutter installed at the housing to allow carrying of the pod between the pod carrying region and an outside region of the housing, an air intake installed at the housing for sucking clean air into the pod carrying region from the outside region of the housing, and an exhaust port configured to exhaust clean air from the pod carrying region. For example, such a conventional semiconductor manufacturing apparatus is disclosed in Patent Document 1 below.

[Patent Document 1] Japanese Unexamined Patent Application Publication No. 2002-43198

For example, in a semiconductor manufacturing apparatus configured to suck clean air from a front region of a housing to the inside of the housing through a front upper part of the housing, an air intake is provided at the front upper part of the housing as an air sucking hole for sucking clean air from the front region of the housing to the inside of the housing. Thus, the air intake provided at the front upper part of the housing is always opened, and a simple cover such as a porous punched panel is placed to cover the air intake.

To suck air into the housing forcibly and maintain the pressure inside the housing positive, a fan may be installed at the air intake. In this case, the fan is usually installed at a secondary side (downstream side) of the punched panel.

In general, air is sucked into the housing through the air intake and is exhausted from the housing through an exhaust port provided at a lower side of a pod carrying region of the housing, so that particles generated in the pod carrying region can be discharged together with the air exhausted from the housing.

However, if a door provided at the inside of an I/O stage (the inside of the housing) is opened when a pod is carried into the housing through an I/O shutter, since there exist two openings at the air intake and the I/O stage of the pod carrying region, downward clean air flows are disturbed, and thus turbulent or adverse clean air flows are generated. Therefore, particles flow outward from the housing together with the clean air.

Particles such as dust and oil particles dispersed to the outside of the housing (for example, to a work space of a clean room at which a pod is inserted into or taken out of the housing of the semiconductor manufacturing apparatus or maintenance works are performed) are introduced into a clean space of the semiconductor manufacturing apparatus via air or a human body during an maintenance or assembly adjustment operation, and when wafers are carried, the particles are attached to the wafers, so that the manufacturing yield of the wafers is undesirably affected by the particles.

### SUMMARY OF THE INVENTION

An object of the present invention is to provide a substrate processing apparatus, in which an outflow of particles generated in a housing can be prevented and a stable down flow can be created in the housing.

According to an aspect of the present invention, there is provided a substrate processing apparatus comprising: a substrate processing region comprising a process furnace configured to process a substrate; a container carrying region comprising a carrying device configured to carry a container accommodating the substrate; a housing in which the substrate processing region and the container carrying region are provided; a first opening formed at the housing for carrying the container between the container carrying region and an outside region of the housing through the first opening; a second opening formed at the housing for sucking gas into the container carrying region from the outside region of the housing through the second opening; an exhaust port configured to exhaust gas from the container carrying region; a door body configured to close the first and second openings; and a control unit configured to control the door body so as to open one of the first and second openings and close the other.

According to another aspect of the present invention, there is provided a method of manufacturing a semiconductor device, the method comprising: exhausting gas out of a housing through an exhaust port while sucking gas from an outside region of the housing into a container carrying region through a second opening in a sate where a first opening formed at the housing is closed; exhausting gas out of the housing through the exhaust port while sucking gas from the outside region of the housing into the container carrying region through the first opening after opening the first opening and closing at least a part of the second opening using a door body; carrying a container into the container carrying region from the outside region of the housing through the first opening; and processing a substrate accommodated in the container at a process furnace.

### BRIEF DESCRIPTION OF THE DRAWINGS

FIG. 1 is a schematic perspective view illustrating a batch type chemical vapor deposition (CVD) apparatus according to an embodiment of the present invention.

FIG. 2 is a side sectional view illustrating the batch type CVD apparatus.

FIG. 3 is a side sectional view illustrating main parts of the batch type CVD apparatus.

FIG. 4 is a vertical sectional view illustrating a reaction furnace.

FIG. 5 is a side sectional view illustrating main parts of a batch type CVD apparatus according to a second embodiment of the present invention.

### DETAILED DESCRIPTION OF THE PREFERRED EMBODIMENTS

An embodiment of the present invention will be described hereinafter with reference to the attached drawings.

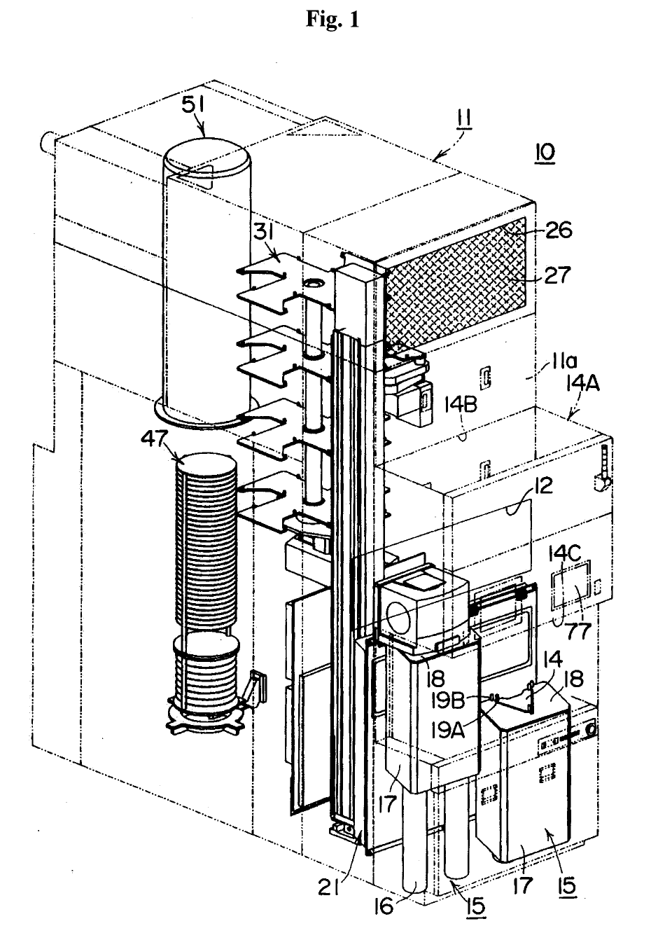

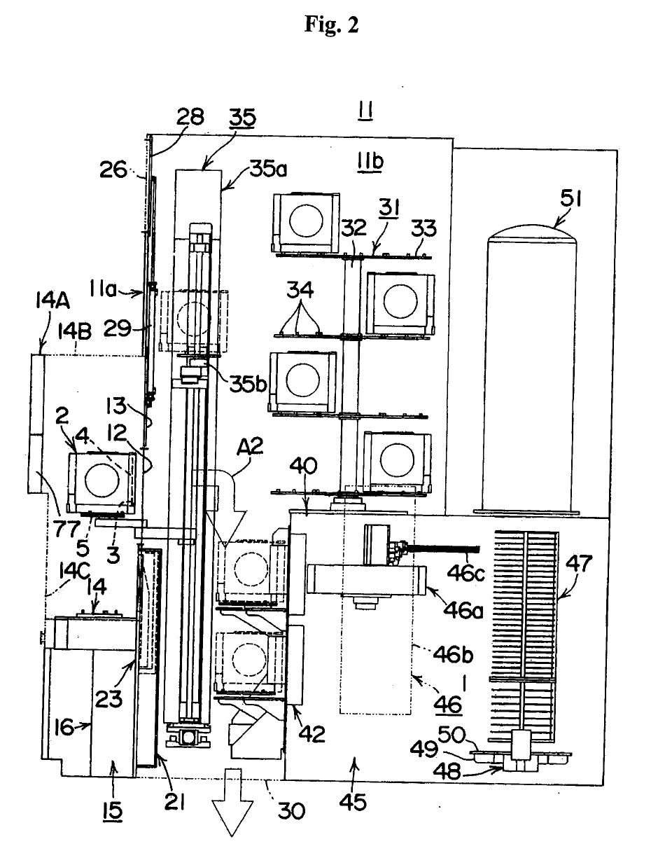

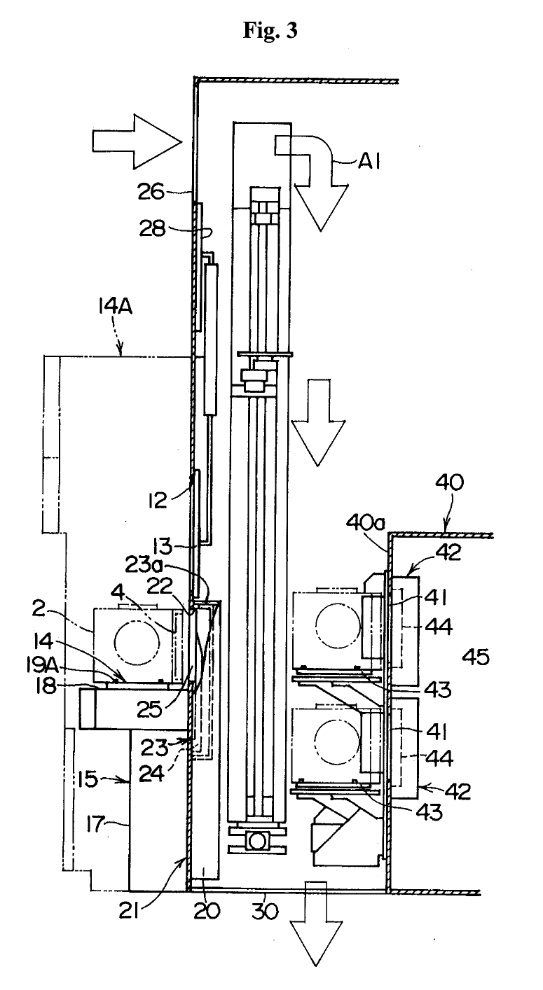

In the current embodiment, a batch type vertical diffusion chemical vapor deposition (CVD) apparatus (hereinafter, referred to as a batch type CVD apparatus) having a structure as shown in FIG. 1, FIG. 2, and FIG. 3 is provided as a substrate processing apparatus relevant to the present invention.

Furthermore, in the current embodiment, pods 2 are used as containers for accommodating substrates such as wafers 1.

A wafer port 3 (refer to FIG. 2) is formed through a sidewall of the pod 2, and a door 4 (refer to FIG. 2) is detachably mounted at the wafer port 3 as a closing cap.

In the bottom surface of the pod 2, three positioning holes 5 (refer to FIG. 2) are formed.

As shown in FIG. 1, FIG. 2, and FIG. 3, a batch type CVD apparatus 10 of the current embodiment includes a main housing 11 as a part of a housing.

A front wall 11a of the main housing 11 constitutes a barrier wall separating the inside and outside of the main housing 11. At a middle height of the front wall 11a, a pod carrying-in and carrying-out port 12 (hereinafter, referred to as a pod carrying port 12) is formed as a first opening. Through the pod carrying port 12, a pod 2 is carried in or out. The pod carrying port 12 is closed or opened using a front shutter 13 (first door body). Hereinafter, the front shutter 13 will be referred to as a first shutter 13.

At the outside of the front wall (barrier wall) 11a of the main housing 11, two I/O stages 14 are installed in parallel. The I/O stages 14 have a triangular flat plate shape and disposed at a front lower side of the pod carrying port 12.

A pod 2 is carried onto the I/O stage 14 or carried away from the I/O stage 14 by an in-process carrying device (also called as an inter-process carrying device) disposed at the outside of the batch type CVD apparatus 10 (at the outside of the housing of the batch type CVD apparatus 10).

Examples of the in-process carrying device include a bottom travel type in-process carrying device such as an automatic guided vehicle (AGV) and a ceiling travel type in-process carrying device such as an overhead hoist transport (OHT). Any one of such devices can be used as the in-process carrying device.

At the front side of the front wall 11a, a box 14A is installed as a front housing. The box 14A encloses the I/O stages 14 and a space located above the I/O stages 14. A top opening 14B is formed in a top wall of the box 14A, and a front opening 14C is formed in a front wall of the box 14A. That is, a pod 2 can be placed onto the I/O stage 14 through the front opening 14C or the top opening 14B.

The box 14A and the main housing 11 constitute the housing of the batch type CVD apparatus 10.

A controller 77 is installed in a front panel of the box 14A. Pod elevators 15 are installed at the I/O stages 14 for moving pods 2 upward and downward. The pod elevator 15 moves the pod 2 between the height of the I/O stage 14 and the height of the pod carrying port 12.

The pod elevator 15 includes a cylinder device 16 as an elevator driving device, and the cylinder device 16 is covered with a cover 17. A holding plate 18 is fixed to an upper end of a piston rod of the cylinder device 16 in a horizontal orientation, and the cover 17 is fixed to the holding plate 18 in a suspended state.

Triangular relief holes are formed in the holding plate 18 at positions corresponding to the I/O stage 14. Outer kinematical pins 19B protrude respectively from apexes of the triangular relief holes, which are located at outer positions of inner kinematical pins 19A protruding from triangular apexes of the I/O stage 14, respectively.

An airtight housing 21 is installed at the inner side of the front wall 11a of the main housing 11 to constitute a loadlock chamber 20. The height of the airtight housing 21 corresponds to the height of the I/O stage 14. The loadlock chamber 20 constitutes an airtight chamber in which inert gas such as nitrogen gas can be filled and stably kept.

A door port 22 is formed at the front wall 11a of the main housing 11 at a position facing the upper side of the loadlock chamber 20. The door port 22 has a size corresponding to the door 4 of a pod 2 placed on the I/O stage 14 (a size larger than the door 4 of the pod 2).

A pod opener 23 is installed in the loadlock chamber 20. The pod opener 23 is used to open or close the wafer port 3 of a pod 2 placed on the I/O stage 14 and the door port 22 of the front wall 11a.

The pod opener 23 includes a movable board 24 and a closer 25. The movable board 24 is movable in a forward/backward direction (perpendicular direction) and an upward/downward direction (parallel direction) with respect to the door port 22. The closer 25 is moved by the movable board 24. The closer 25 can be used to hold the door 4 of a pod 2 and close the door port 22.

That is, the pod opener 23 can be used to open or close the wafer port 3 of a pod 2 and the door port 22 by moving the closer 25 in forward/backward and upward/downward directions by using the movable board 24 in a state that the closer 25 holds the door 4 of the pod 2.

At the pod opener 23, a mapping device 23a is installed for mapping wafers 1 disposed in a pod 2.

A pod store chamber 11b is formed in an inner front region of the main housing 11. A rotary pod shelf 31 is installed in the pod store chamber 11b. The rotary pod shelf 31 is disposed at an approximately upper center part of the pod store chamber 11b in a front-to-back direction of the pod store chamber 11b.

The rotary pod shelf 31 includes a post 32 and a plurality of shelf plates 33. The post 32 is vertically installed in a manner such that the post 32 can be intermittently rotated on a horizontal plane. The shelf plates 33 are disposed at upper, middle, and lower ends of the post 32 and are radially supported. A plurality of pods 2 can be placed on each of the shelf plates 33.

A plurality of shelf kinematical pins 34 protrude from the top surface of each of the shelf plates 33. The shelf kinematical pins 34 can be inserted in the positioning holes 5 of a pod 2.

A pod carrying device 35 is installed in the pod store chamber 11b. The pod carrying device 35 includes a pod elevator 35a and a handling device 35b. The handling device 35b includes a holder (also referred to as a holding mechanism) for support the bottom surface of a pod 2.

The pod carrying device 35 is used to carry a pod 2 among the holding plate 18, the rotary pod shelf 31, and rest boards 43 of pod openers 42 (described later) by continuously operating the pod elevator 35a and the handling device 35b.

Therefore, the pod store chamber 11b constitutes a pod carrying region (container carrying region) in which a carrying device is provided for carrying pods 2.

At the front wall 11a of the main housing 11, an air intake 26 is formed above the pod carrying port 12, and a punched panel 27 (refer to FIG. 1) is installed at the air intake 26. The air intake 26 is installed at the housing to form a second opening through which outside gas is sucked from the outside of the housing into the pod store chamber 11b constituting a container carrying region.

Laminar flows can be easily formed by air sucked into the housing owing to the punched panel 27; however, the punched panel 27 can be omitted.

An air intake shutter 28 (hereinafter, referred to as a second shutter 28) is installed at a side of the front wall 11a of the main housing 11 facing the pod store chamber 11b as a second door body for closing the second opening. The second shutter 28 has a size suitable for closing the air intake 26.

A bilateral rod cylinder device 29 is installed at a side of the front wall 11a of the main housing 11 facing the pod store chamber 11b in a manner such that the bilateral rod cylinder device 29 extend vertically. The second shutter 28 is installed at an upper rod of the bilateral rod cylinder device 29, and the first shutter 13 is installed at a lower rod of the bilateral rod cylinder device 29.

The bilateral rod cylinder device 29 is connected to the controller 77, and the controller 77 controls the first shutter 13 and the second shutter 28 through the bilateral rod cylinder device 29 for opening one of the pod carrying port 12 (first opening) and the air intake 26 and closing the other.

At the bottom surface of the pod store chamber 11b constituting a container carrying region, an exhaust port 30 is formed to exhaust gas (clean air) from the pod store chamber 11b. Clean air of the pod store chamber 11b flows downward through the exhaust port 30.

In addition, it is preferable that the exhaust port 30 be connected to an exhaust duct (not shown) so that fluid flowing through the exhaust port 30 can be isolated from a work space of a clean room. Owing to the exhaust duct, gas exhausted from the container carrying region through the exhaust port 30 can be surely discharged to the outside of the clean room.

As shown in FIG. 2, a sub housing 40 is constructed in the main housing 11 at an approximately lower center region of the main housing 11 in a front-to-back direction in a manner such that the sub housing 40 extends to the rear side of the main housing 11.

At a front wall 40a of the sub housing 40, a pair of wafer carrying-in and carrying-out ports 41 (hereinafter, referred to as wafer carrying ports 41) are arranged side by side in two stages in a vertical direction. Through the wafer carrying ports 41, wafers 1 can be carried into or out of the sub housing 40. The pod openers 42 are installed at the wafer carrying ports 41, respectively.

Each of the pod openers 42 includes a rest board 43 on which a pod 2 can be placed, and an attaching/detaching mechanism 44 configured to attach and detach the door 4 of a pod 2. The wafer port 3 of a pod 2 placed on the rest board 43 can be closed or opened by detaching or attaching the door 4 of the pod 2 using the pod opener 42.

The sub housing 40 forms an auxiliary chamber 45. The auxiliary chamber 45 is fluidically distant from the pod store chamber 11b in which the pod carrying device 35 and the rotary pod shelf 31.

At the front region of the auxiliary chamber 45, a wafer transfer mechanism 46 is installed. The wafer transfer mechanism 46 includes a wafer transfer device 46a, a wafer transfer device elevator 46b, and tweezers 46c. The tweezers 46c holds a wafer 1, and the wafer transfer device 46a rotates or linearly moves the tweezers 46c on a horizontal plane. The wafer transfer device elevator 46b is installed at a right end part of the front region of the auxiliary chamber 45. The wafer transfer device elevator 46b moves the wafer transfer device 46a upward and downward.

The wafer transfer mechanism 46 transfers a wafer 1 from a pod 2 to a boat 47 and charges the wafer 1 into the boat 47 in a way of holding the wafer 1 with the tweezers 46c and moving the tweezers 46c through a combinational operation of the wafer transfer device 46a and the wafer transfer device elevator 46b.

In addition, the wafer transfer mechanism 46 is also used to discharge the wafer 1 from the boat 47 by holding the wafer 1 with the tweezers 46c and carry the wafer 1 from the boat 47 to the pod 2 to return the wafer 1 to the pod 2.

The controller 77 controls operations of every parts of the batch type CVD apparatus 10, such as the pod elevator 15, the pod opener 23, the bilateral rod cylinder device 29, the rotary pod shelf 31, the pod carrying device 35, the pod opener 42, and the wafer transfer mechanism 46.

At the rear region of the auxiliary chamber 45, a boat elevator 48 is installed to move the boat 47 upward and downward.

At an arm 49 connected to an elevator base of the boat elevator 48 as a connection mechanism, a seal cap 50 is horizontally installed. The seal cap 50 can support the boat 47 vertically and seal a lower end of a process furnace 51 (described later).

The boat 47 includes a plurality of holding members. In the boat 47, a plurality of wafers 1 (for example, fifty to one hundred twenty five wafers 1) can be held in horizontal positions in a manner such that the wafers 1 are vertically arranged with the centers of the wafers 1 being aligned.

The process furnace 51 is installed at the top side of the sub housing 40. The process furnace 51 and the sub housing 40 constitute a substrate processing region. That is, the main housing 11 constitutes the housing of the batch type CVD apparatus 10, in which the substrate processing region is defined to process wafers 1 using the process furnace 51 and the container carrying region is defined by the pod store chamber 11b.

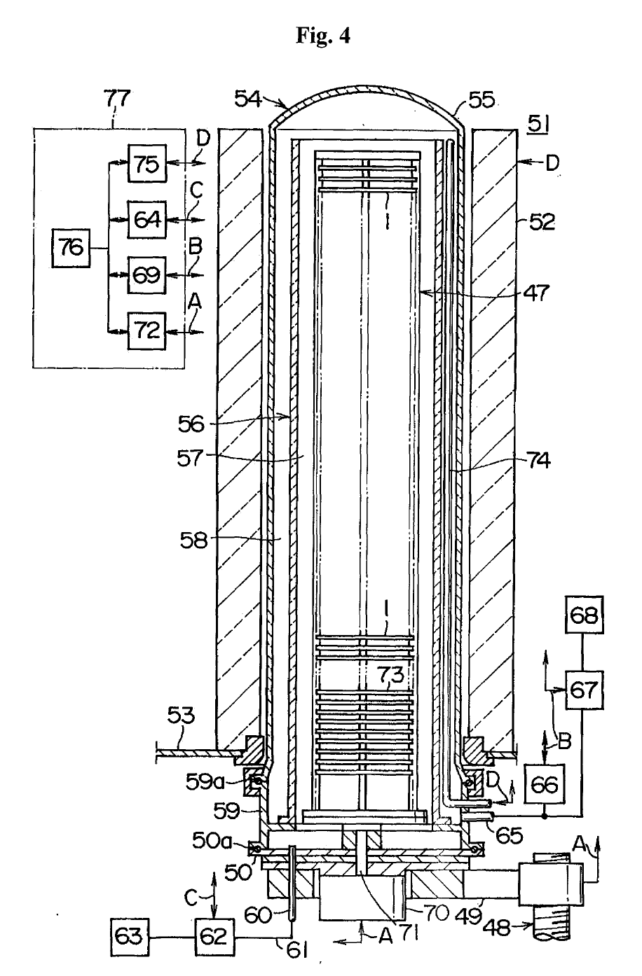

As shown in FIG. 4, the process furnace 51 includes a heater 52 as a heating mechanism.

The heater 52 has a cylindrical shape and is vertically installed on a heater base 53 used as a holding plate.

Inside the heater 52, a process tube 54 is installed coaxially with the heater 52 as a reaction tube. The process tube 54 includes an outer tube 55 as an outer reaction tube, and an inner tube 56 installed in the outer tube 55 as an inner reaction tube.

For example, the outer tube 55 is made of a heat resistant material such as quartz (SiO₂) or silicon carbide (SiC). The inner diameter of the outer tube 55 is greater than the outer diameter of the inner tube 56, and the outer tube 55 has a cylindrical shape with a closed top end and an opened bottom end.

For example, the inner tube 56 is made of a heat resistant material such as quartz or silicon carbide. The inner tube 56 has a cylindrical shape with opened top and bottom ends. The hollow inside of the inner tube 56 forms a process chamber 57. The process chamber 57 can accommodate the boat 47 in which wafers 1 are held in horizontal positions and vertically arranged in multiple stages.

A cylindrical gap 58 is formed between the outer tube 55 and the inner tube 56.

At the lower side of the outer tube 55, a manifold 59 is installed coaxially with the outer tube 55. For example, the manifold 59 is made of stainless steel. The manifold 59 has a cylindrical shape with opened top and bottom ends. The manifold 59 is engaged with the outer tube 55 and the inner tube 56 and supports the outer tube 55 and the inner tube 56.

The manifold 59 is supported by the heater base 53 such that the process tube 54 can be vertically positioned.

The process tube 54 and the manifold 59 constitute a reaction vessel.

Between the manifold 59 and the outer tube 55, an O-ring 59a is installed as a seal.

A nozzle 60 is connected from a gas introduction part to the seal cap 50. The nozzle 60 communicates with the process chamber 57. A gas supply pipe 61 is connected to the nozzle 60.

A gas supply source 63 is connected to a side (upstream side) of the gas supply pipe 61 opposite to the nozzle 60, and a mass flow controller (MFC) 62 is disposed between the gas supply source 63 and the gas supply pipe 61. The MFC 62 constitutes a gas flow rate controller. The gas supply source 63 supplies gas such as process gas and inert gas.

A gas flow rate control unit 64 is electrically connected to the MFC 62 through an electric wire C. The gas flow rate control unit 64 controls the MFC 62 so that a desired amount of gas can be supplied at a desired time.

At the manifold 59, an exhaust pipe 65 is installed to exhaust the inside atmosphere of the process chamber 57. The exhaust pipe 65 is located at a lower end part of the cylindrical gap 58 and communicates with the cylindrical gap 58.

An exhaust device 68 is connected to a side (downstream side) of the exhaust pipe 65 opposite to the manifold 59, and a pressure sensor 66 and a pressure regulator 67 are disposed between the circulation lines 68 and the exhaust pipe 65. The pressure sensor 66 constitutes a pressure detector. The exhaust device 68 is configured by, for example, a vacuum pump. The pressure sensor 66, the pressure regulator 67, and the exhaust device 68 are used to exhaust the inside of the process chamber 57 to a predetermined pressure (vacuum degree).

A pressure control unit 69 is electrically connected to the pressure regulator 67 and the pressure sensor 66 through electric wires B. The pressure control unit 69 controls the pressure regulator 67 based on pressure information measured using the pressure sensor 66 so that the inside pressure of the process chamber 57 can be controlled to a desired level at a desired time.

The seal cap 50 is brought into contact with the bottom end of the manifold 59 from the bottom side of the manifold 59 in a vertical direction. The seal cap 50 constitutes a furnace throat cover used for air-tightly sealing the opened bottom end of the manifold 59.

For example, the seal cap 50 is made of a metal such as stainless steel and has a circular disk shape. An O-ring 50a is installed on the top surface of the seal cap 50 as a seal. The O-ring 50a is in contact with the bottom end of the manifold 59.

At a side of the seal cap 50 opposite to the process chamber 57, a rotary mechanism 70 is installed for rotating the boat 47. A rotation shaft 71 of the rotary mechanism 70 is connected to the boat 47 through the seal cap 50. By rotating the boat 47 via the rotation shaft 71, wafers 1 of the boat 47 can be rotated.

A driving control unit 72 is electrically connected to the rotary mechanism 70 and the boat elevator 48 through electric wires A. The driving control unit 72 controls the rotary mechanism 70 and the boat elevator 48 so that the rotary mechanism 70 and the boat elevator 48 can be operated at a desired time.

For example, the boat 47 is made of a heat resistant material such as quartz or silicon carbide. The boat 47 holds a plurality of wafers 1 in horizontal positions in a manner such that the wafers 1 are arranged in multiple stages with the centers of the wafers 1 being aligned.

In the lower part of the boat 47, a plurality of insulating plates 73 are horizontally positioned and arranged in multiple stages. For example, the insulating plates 73 are made of a heat resistant material such as quartz or silicon carbide and have a circular disk shape. The insulating plates 73 constitute an insulating member. The insulating plates 73 prevent heat transfer from the heater 52 to the manifold 59.

In the process tube 54, a temperature sensor 74 is installed. The temperature sensor 74 constitutes a temperature detector. A temperature control unit 75 is electrically connected to the heater 52 and the temperature sensor 74 through electrical wires D.

The temperature control unit 75 controls power to the heater 52 based on temperature information detected by the temperature sensor 74 so that the heater 52 can be operated to obtain desired temperature distribution inside the process chamber 57 at a desired time.

The gas flow rate control unit 64, the pressure control unit 69, the driving control unit 72, and the temperature control unit 75 are also used to constitute a manipulation unit and an input/output unit, and are connected to a main control unit 76 used to control the overall operation of the batch type CVD apparatus 10.

The controller 77 is constituted by the gas flow rate control unit 64, the pressure control unit 69, the driving control unit 72, the temperature control unit 75, and the main control unit 76.

Next, a process of forming a film using the above-described batch type CVD apparatus in an IC manufacturing method will be explained according to an embodiment of the present invention.

In the following description, each part of the batch type CVD apparatus is controlled by the controller 77.

As shown in FIG. 3, when a pod 2 is not carried from the outside of the main housing 11 to the pod store chamber 11b, the upper and lower rods of the bilateral rod cylinder device 29 are in lower positions. In this state, the pod carrying port 12 is closed by the first shutter 13 but the air intake 26 is not closed by the second shutter 28.

Therefore, clean air is introduced into the pod store chamber 11b from the outside of the main housing 11 through only the air intake 26. The clean air introduced into the pod store chamber 11b flows downward throughout the pod store chamber 11b and is exhausted through the exhaust port 30 formed through the bottom surface of the pod store chamber 11b as indicated by arrow A1 of FIG. 3.

As explained above, since air flows down in the pod store chamber 11b, particles generated in the pod store chamber 11b can be surely exhausted through the exhaust port 30 to the outside of the pod store chamber 11b (the outside of the clean room), at least to the outside of the work space of the clean room.

When a pod 2 is carried into the pod store chamber 11b through the pod carrying port 12, as shown in FIG. 2, the upper and lower rods of the bilateral rod cylinder device 29 are in upper positions. In this state, the pod carrying port 12 is not closed by the first shutter 13 but the air intake 26 is closed by the second shutter 28.

Therefore, clean air is introduced into the pod store chamber 11b from the outside of the main housing 11 through only the pod carrying port 12. The clean air introduced into the pod store chamber 11b flows downward from the pod carrying port 12 and is exhausted through the exhaust port 30 formed through the bottom surface of the pod store chamber 11b as indicated by arrow A2 of FIG. 2.

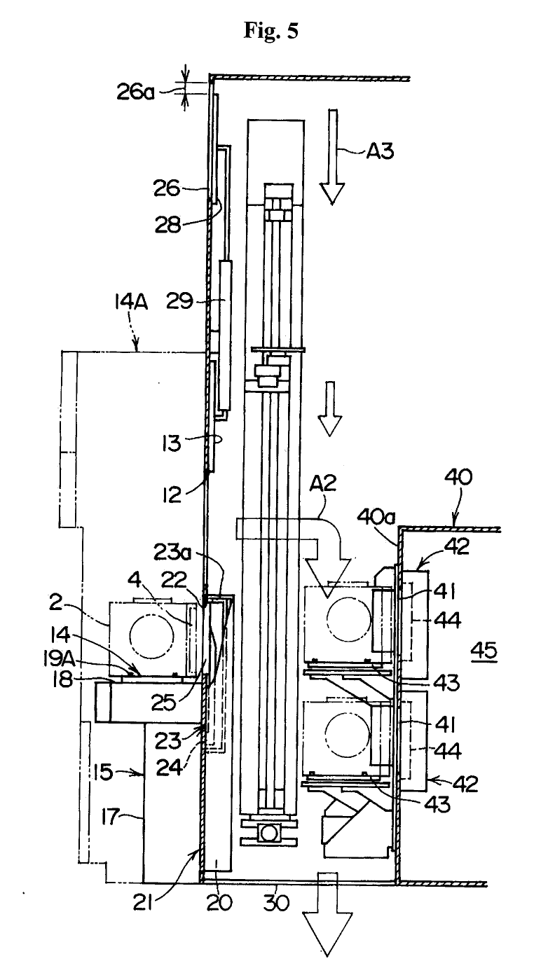

During the above-described operation, although air flows into the pod store chamber 11b through a small gap 26a as indicated by arrow A3 in FIG. 5, since only the handling device 35b of the parts of the pod carrying device 35 which are possible main sources of dust is operated at the front of the pod carrying port 12, most particles flow together with the air flow A2 and are prevented from flowing reversely to the upside of the pod store chamber 11b by the secondary air flow A3, so that the particles can be exhausted through the exhaust port 30.

The in-process carrying device (e.g., AGV or OHT) carries a pod 2 onto the I/O stage 14 through front opening 14C or the top opening 14B of the box 14A for supplying the pod 2 to the inside of the batch type CVD apparatus 10.

At this time, the inner kinematical pins 19A of the I/O stage 14 are inserted into the positioning holes 5 formed in the bottom surface of the pod 2, the position of the pod 2 on the I/O stage 14 can be determined.

Thereafter, the pod 2 is moved toward the pod opener 23, and the door 4 of the pod 2 is held by the closer 25 of the pod opener 23. Then, the movable board 24 is moved backward to detach (demount) the door 4 from the wafer port 3 of the pod 2.

After that, the movable board 24 is moved downward in the loadlock chamber 20, and thus the closer 25 is moved away from the wafer port 3.

After the wafer port 3 is opened, the mapping device 23a maps wafers 1 disposed inside the pod 2.

After the mapping, the movable board 24 is moved upward to locate the closer 25 at the wafer port 3. Then, the movable board 24 is moved forward so that the door 4 can be attached (mounted) to the wafer port 3 by the closer 25.

Thereafter, the pod elevator 15 lifts the pod 2 from the I/O stage 14 to the height of the pod carrying port 12. In detail, the cylinder device 16 lifts the holding plate 18 using its piston rod to raise the pod 2 placed on the I/O stage 14 by using the holding plate 18. At this time, the outer kinematical pins 19B of the holding plate 18 are inserted into the positioning holes 5 of the bottom surface of the pod 2 at positions outside the inner kinematical pins 19A of the I/O stage 14, such that the position of the pod 2 can be determined.

When the pod 2 is raised to the height of the pod carrying port 12, as explained above, the upper and lower rods of the bilateral rod cylinder device 29 are upwardly moved to open the pod carrying port 12 by shifting the first shutter 13 and close the air intake 26 by shifting the second shutter 28.

Next, as shown in FIG. 2, the handling device 35b of the pod carrying device 35 is inserted in the pod carrying port 12 to lift the pod 2 supported on the holding plate 18.

Then, the handling device 35b of the pod carrying device 35 carries the lifted pod 2 into the main housing 11 through the pod carrying port 12, and the upper and lower rods of the bilateral rod cylinder device 29 are moved downward to close the pod carrying port 12 by shifting the first shutter 13 and open the air intake 26 by shifting the second shutter 28. Thereafter, the pod carrying device 35 carries the pod 2 toward a predetermined one of the shelf plates 33 of the rotary pod shelf 31 and places the pod 2 on the shelf plate 33.

At this time, the shelf kinematical pins 34 of the shelf plate 33 are inserted into the positioning holes 5 of the bottom surface of the pod 2 so that the position of the pod 2 on the shelf plate 33 can be determined.

The pod 2 is temporarily stored on the shelf plate 33.

Thereafter, the pod carrying device 35 carries the pod 2 from the shelf plate 33 toward one of the pod openers 42 and places the pod 2 on the rest board 43 of the pod opener 42.

At this time, the pod carrying port 41 of the pod opener 42 is closed by the attaching/detaching mechanism 44, and the auxiliary chamber 45 is filled with introduced clean air.

The clean air filled in the auxiliary chamber 45 is nitrogen gas. In this state, for example, the oxygen concentration of the inside of the auxiliary chamber 45 is 20 ppm or lower, which is much lower than the oxygen concentration of the inside (atmospheric environment) of the main housing 11.

In some cases, the pod carrying device 35 may carry a pod 2, introduced into the main housing 11 through the pod carrying port 12, directly to the pod opener 42.

When the pod 2 is carried inside the pod store chamber 11b, as shown in FIG. 3, the upper and lower rods of the bilateral rod cylinder device 29 are in lower positions. Therefore, the pod carrying port 12 is closed by the first shutter 13 but the air intake 26 is not closed by the second shutter 28.

Thus, clean air is introduced to the pod store chamber 11b from the outside of the main housing 11 through only the air intake 26. The clean air introduced into the pod store chamber 11b flows downward throughout the pod store chamber 11b and is exhausted through the exhaust port 30 formed in the bottom surface of the pod store chamber 11b as indicated by arrow A1 of FIG. 3.

Since a down flow is created inside the pod store chamber 11b as described above, particles generated in the pod store chamber 11b can be surely exhausted through the exhaust port 30 to the outside of the pod store chamber 11b (the outside of the clean room), at least to the outside of the work space of the clean room.

The pod opener 42 moves the rest board 43 to push the opened side of the pod 2 toward the vicinity of the pod carrying port 41 of the front wall 40a.

Next, the pod opener 42 detaches the door 4 of the pod 2 using the attaching/detaching mechanism 44 to open the wafer port 3 of the pod 2.

At this time, since the wafers 1 disposed inside the pod 2 are already mapped at the I/O stage 14, mapping may be omitted.

After the pod 2 is opened by the pod opener 42, the wafer transfer device 46a picks up the wafer 1 from the pod 2 through the wafer port 3 using the tweezers 46c and carries the wafer 1 to a notch aligning device (not shown). The notch aligning device is used to align the orientation of the wafer 1. After the alignment, the wafer transfer device 46a picks up the wafer 1 from the notch aligning device using the tweezers 46c and carries the wafer 1 to the boat 47. Then, the wafer transfer device 46a charges the wafer 1 into the boat 47.

Thereafter, the wafer transfer device 46a moves back to the pod 2 for charging of the next wafer 1.

While the wafer transfer mechanism 46 carries wafers 1 from one of the pod openers 42 for charging the wafers 1 into the boat 47, the pod carrying device 35 carries another (next) pod 2 from the rotary pod shelf 31 to the other of the pod openers 42 and places the next pod 2 on the other of the pod opener 42.

At this time, opening of the next pod 2 is simultaneously performed by the other of the pod openers 42.

After a predetermined number of wafers 1 are charged into the boat 47, a furnace throat shutter (not shown) is moved to open the lower end of the process furnace 51.

Next, the boat 47 in which a group of wafers 1 is held is loaded into the process furnace 51 (boat loading) as the seal cap 50 is lifted by the boat elevator 48.

Hereinafter, an explanation will be given on a method of forming a thin film on a wafer 1 using the process furnace 51 by a CVD method.

In the following description, parts of the process furnace 51 are controlled by the controller 77.

After a plurality of wafers 1 are charged into the boat 47 (wafer charging), as shown in FIG. 4, the boat elevator 48 lifts the boat 47 to load the boat 47 into the process chamber 57 (boat loading).

In this state, the seal cap 50 seals the lower end of the manifold 59 using the O-ring 50a.

The exhaust device 68 exhausts the inside of the process chamber 57 to a desired pressure (vacuum degree). At this time, the pressure sensor 66 measures the pressure inside the process chamber 57. Based on the pressure measured by the pressure sensor 66, the pressure regulator 67 is feedback-controlled.

The heater 52 heats the inside of the process chamber 57 to a desired temperature. At this time, to obtained desired temperature distribution inside the process chamber 57, power to the heater 52 is feedback-controlled based on temperature information detected by the temperature sensor 74.

Next, the boat 47 is rotated by the rotary mechanism 70 so that the wafers 1 can also be rotated.

Thereafter, gas supplied from the gas supply source 63 and controlled in flow rate by the MFC 62 is introduced into the process chamber 57 through the gas supply pipe 61 and the nozzle 60.

The introduced gas flows upward in the process chamber 57 and is discharged through the opened top end of the inner tube 56 to the cylindrical gap 58 where the gas is exhausted to the exhaust pipe 65.

When the gas passes through the inside of the process chamber 57, the gas makes contact with surfaces of the wafers 1. Therefore, thin films are deposited on the surfaces of the wafers 1 by thermal CVD reactions.

After a predetermined process time, inert gas is supplied from the gas supply source 63 through the gas supply pipe 61 for replacing the inside atmosphere of the process chamber 57 with the inert gas and adjusting the pressure inside the process chamber 57 back to ambient pressure.

Thereafter, the boat elevator 48 moves the seal cap 50 downward for opening the lower end of the manifold 59 and unloading the boat 47 in which the processed wafers 1 are held from the process tube 54 through the opened lower end of the manifold 59 (boat unloading).

After the boat unloading, the wafer transfer mechanism 46 discharges the wafers 1 from the boat 47 using the wafer transfer device 46a (wafer discharging) and carries the wafers 1 to the pod opener 42 to return the wafers 1 to the pod 2 which is empty and previously carried to the pod opener 42.

After a predetermined number of processed wafers 1 are accommodated in the pod 2, the pod opener 42 attaches the door 4 of the pod 2 to the wafer port 3 of the pod 2.

The pod carrying device 35 picks up the pod 2 from the pod opener 42 and carries the pod 2 to a predetermined one of the shelf plates 33 of the rotary pod shelf 31.

At this time, as shown in FIG. 3, the upper and lower rods of the bilateral rod cylinder device 29 are moved downward. Thus, since the pod carrying port 12 is closed by the first shutter 13 and the air intake 26 is not closed by the second shutter 28, clean air is introduced into the pod store chamber 11b from the outside of the main housing 11 through only the air intake 26 so that the clean air can flow downward throughout the pod store chamber 11b. Therefore, particles generated in the pod store chamber 11b can be surely exhausted through the exhaust port 30 to the outside of the pod store chamber 11b (the outside of the clean room), at least to the outside of the work space of the clean room.

The pod 2 is temporarily stored.

Thereafter, the pod carrying device 35 carries the pod 2 from the shelf plate 33 to the pod carrying port 12 and places the pod 2 on the holding plate 18 of the pod elevator 15 through the pod carrying port 12.

When the pod 2 is carried out through the pod carrying port 12, the upper and lower rods of the bilateral rod cylinder device 29 are moved upward. Therefore, the first shutter 13 is shifted to open the pod carrying port 12, and the second shutter 28 is shifted to close the air intake 26, such that clean air is introduced into the pod store chamber 11b from the outside of the main housing 11 through only the pod carrying port 12 to create a down flow from the pod carrying port 12. Thus, particles generated in the pod store chamber 11b can be surely exhausted through the exhaust port 30 to the outside of the pod store chamber 11b (the outside of the clean room), at least to the outside of the work space of the clean room.

In some cases, the pod carrying device 35 may carry a pod 2, in which processed wafers 1 are accommodated, directly from the pod opener 42 to the pod carrying port 12, and place the pod 2 on the holding plate 18 through the pod carrying port 12.

After the pod carrying device 35 carries the pod 2 onto the holding plate 18, the upper and lower rods of the bilateral rod cylinder device 29 are moved downward. Therefore, since the pod carrying port 12 is closed by the first shutter 13 and the air intake 26 is not closed by the second shutter 28, clean air is introduced into the pod store chamber 11b from the outside of the main housing 11 through only the air intake 26 so that the clean air flows downward throughout the pod store chamber 11b. Therefore, particles generated in the pod store chamber 11b can be surely exhausted through the exhaust port 30 to the outside of the pod store chamber 11b.

At the other side, the pod elevator 15 moves the holding plate 18 downward by using its cylinder device 16 so as to place the pod 2 on the I/O stage 14.

Thereafter, the in-process carrying device (e.g., AGV or OHT) picks up the pod 2 from the I/O stage 14 through the front opening 14C or the top opening 14B of the box 14A in order to carry the pod 2 from the batch type CVD apparatus 10 to another place for the next process.

According to the above-described embodiment, at least one of the following effects can be attained.

(1) When a pod is not carried into or out of the pod store chamber, the upper and lower rods of the bilateral rod cylinder device are moved downward to close the pod carrying port by using the first shutter and open the air intake by shifting the second shutter, so that clean air can be introduced into the pod store chamber from the outside of the housing through only the air intake to allow the clean air to flow downward throughout the pod store chamber. Therefore, particles generated in the pod store chamber can be surely exhausted through the exhaust port to the outside of the pod store chamber.

(2) When a pod is carried into or out of the pod store chamber, the upper and lower rods of the bilateral rod cylinder device are moved upward to open the pod carrying port by shifting the first shutter and close the air intake by using the second shutter, so that clean air can be introduced into the pod store chamber from the outside of the housing through only the pod carrying pod to allow the clean air to flow downward form the pod carrying port. Therefore, particles generated in the pod store chamber can be surely exhausted through the exhaust port to the outside of the pod store chamber.

(3) Since the cleaning level of the inside and outside of the housing can be improved, the process yield can be increased.

FIG. 5 illustrates main parts of a batch type CVD apparatus according to a second embodiment of the present invention.

If the air intake 26 is completely closed by the second shutter 28 when a pod 2 is carried in the pod store chamber 11b with the pod carrying port 12 being opened, a stagnant (deposition) zone can be formed at an upper space of the pod store chamber 11b.

In the current embodiment, when the air intake 26 is closed by the second shutter 28, a small gap (small clean air suction hole) 26a is formed by the second shutter 28 such that a small amount of clean air can be introduced into the pod store chamber 11b from the outside of the main housing 11 through the small gap 26a.

That is, owing to the gap 26a, a down flow A3 can be created at the upper space of the pod store chamber 11b in a manner such that the down flow A3 is pulled toward a down flow A2 created at the lower space of the pod store chamber 11b by air introduced through the pod carrying port 12. Therefore, generation of a stagnant (deposition) zone at the upper space of the pod store chamber 11b can be prevented.

Here, the small amount is resulted from the relationship that the size of the air intake 26 closed by the second shutter 28 is smaller than the size of the pod carrying port 12 closed by the first shutter 13.

It is preferable that the gap 26a be formed at an upper end part of the air intake 26 for sucking a small amount of air therethrough. In this case, generation of a stagnant zone can be surely prevented throughout the entire region of the pod store chamber 11b.

Here, it will be easily understood that it is difficult to balance three factors: the size of the pod carrying port 12 not closed by the first shutter 13 (i.e., the opened size of the pod carrying port 12), the amount of air exhausted from the pod store chamber 11b, and the opened size of the air intake 26 through which a small amount of air is sucked. Therefore, it is preferable that the three factors be preset by measuring flows of clean air.

Preferably, the main surface of the second shutter 28 is smaller than the size of the air intake 26 to create the gap 26a mechanically.

More preferably, the bilateral rod cylinder device 29 used a driving device for actuating the second shutter 28 may be replaced with a ball screw motor type linear actuator to adjust the stroke of the driving device. In this case, the region of the air intake 26 closed by the second shutter 28 can be finely adjusted with ease.

Alternatively, instead of forming the gap 26a at the air intake 26, the gap 26a may be formed between coupled surfaces of the air intake 26 and the second shutter 28.

Alternatively, to suck a small amount of clean air from the outside of the main housing 11 into the pod store chamber 11b, a dedicated suction hole may be formed through a front upper side of the pod store chamber 11b.

According to the current embodiment, the following effect can be attained in addition to the above-explained effects attainable in accordance with the previous embodiment.

When the air intake is closed by the second shutter, a small amount of clean air is sucked into the pod store chamber from the outside of the housing to create a down flow can at the upper space of the pod store chamber in a manner such that the down flow is pulled toward a down flow created at the lower space of the pod store chamber by air introduced through the carrying port. Therefore, generation of a stagnant (deposition) zone at the upper space of the pod store chamber can be prevented.

The present invention is not limited to the above-described embodiments, and it will be apparent that various modifications can be made therefrom without departing from the spirit and scope of the present invention.

In the above-described embodiments, the air intake is formed at the front upper side of the pod store chamber; however, in the case where an OHT I/O stage is installed at the upper side of the pod store chamber, a pair of shutters operating in association with the OHT I/O stage and the air intake can be installed for the same operations and effects as described above.

In this case, a structure for sucking a small amount of clean air can be formed at the side of the OHT I/O stage like in the second embodiment. That is, a gap or suction hole can be formed at an upstream-side opening when viewed from the exhaust port, so as to prevent generation of a stagnant (deposition) zone throughout the entire region of the pod store chamber (pod carrying region).

The driving device for actuating the shutters is not limited to the bilateral rod cylinder device and the ball screw motor type linear actuator. For example, various devices, such as a device having a rod cylinder at one side or a linear motor, can be used as the driving device.

In the above-described embodiments, a batch type CVD apparatus is illustrated by example; however, the present invention is not limited thereto. The present invention can be applied to various substrate processing apparatuses such as a diffusing apparatus, an annealing apparatus, and an oxidation apparatus.

In the present invention, a substrate is not limited to a wafer; for example, the substrate may be a photomask, a printed circuit substrate, a liquid crystal panel, a compact disk, or a magnetic disk.

According to the present invention, an outflow of particles generated in the housing can be prevented, and a stable down flow can be created in the housing.

(Supplementary Note) The present invention also includes the following preferred embodiments.

(Supplementary Note 1) According to a preferred embodiment of the present invention, there is provided a substrate processing apparatus comprising: a substrate processing region comprising a process furnace configured to process a substrate; a container carrying region comprising a carrying device configured to carry a container accommodating the substrate; a housing in which the substrate processing region and the container carrying region are provided; a first opening formed at the housing for carrying the container between the container carrying region and an outside region of the housing through the first opening; a second opening formed at the housing for sucking gas into the container carrying region from the outside region of the housing through the second opening; an exhaust port configured to exhaust gas from the container carrying region; a door body configured to close the first and second openings; and a control unit configured to control the door body so as to open one of the first and second openings and close the other.

(Supplementary Note 2) According to another preferred embodiment of the present invention, there is provided a method of manufacturing a semiconductor device, the method comprising: exhausting gas out of a housing through an exhaust port while sucking gas from an outside region of the housing into a container carrying region through a second opening in a sate where a first opening formed at the housing is closed; exhausting gas out of the housing through the exhaust port while sucking gas from the outside region of the housing into the container carrying region through the first opening after opening the first opening and closing at least a part of the second opening using a door body; carrying a container into the container carrying region from the outside region of the housing through the first opening; and processing a wafer accommodated in the container at a process furnace.

(Supplementary Note 3) In the substrate processing apparatus of Supplementary Note 1, the door body comprises first and second door bodies configured to open and close the first and second openings individually, and the control unit controls interlocking operations of the first and second door bodies for opening and closing the first and second openings.

(Supplementary Note 4) In the substrate processing apparatus of Supplementary Note 1, the first and second openings have the same size.

(Supplementary Note 5) In the substrate processing apparatus of Supplementary Note 4, the control unit controls the door body such that one of the first and second openings more distant from the exhaust port than the other is not fully closed by the door body.

(Supplementary Note 6) According to another preferred embodiment of the present invention, there is provided a method of manufacturing a semiconductor device using the substrate processing apparatus of Supplementary Note 1, there method comprising: sucking gas into the container carrying region from an outside region of the housing through the second opening and exhausting the gas out of the container carrying region in a sate where the first opening is closed; carrying a container into the container carrying region through the first opening after closing the second opening and opening the first opening; and processing the substrate accommodated in the container at the process furnace.

What is claimed is:

1. A substrate processing apparatus comprising:
a substrate processing region comprising a process furnace configured to process a substrate;
a container carrying region comprising a carrying device configured to carry a container accommodating the substrate;
a housing in which the substrate processing region and the container carrying region are provided;
a first opening formed at the housing for carrying the container between the container carrying region and an outside region of the housing through the first opening;
a second opening formed at the housing for sucking gas into the container carrying region from the outside region of the housing through the second opening;
an exhaust port configured to exhaust gas from the container carrying region;
a door body configured to close the first and second openings; and
a control unit configured to control the door body so as to open one of the first and second openings and close the other.

2. A method of manufacturing a semiconductor device, the method comprising:
exhausting gas out of a housing through an exhaust port while sucking gas from an outside region of the housing into a container carrying region through a second opening in a sate where a first opening formed at the housing is closed;
exhausting gas out of the housing through the exhaust port while sucking gas from the outside region of the housing into the container carrying region through the first opening after opening the first opening and closing at least a part of the second opening using a door body;
carrying a container into the container carrying region from the outside region of the housing through the first opening; and
processing a substrate accommodated in the container at a process furnace.
